(19) United States
(12) Patent Application Publication
(10) Pub. No.: US 2024/0199431 A1
(43) Pub. Date: Jun. 20, 2024

(54) Development of Fluorine-Free Tantalum Carbide Mxene Hybrid Structure as a Biocompatible Material for Supercapacitor Electrodes

(71) Applicant: University of Manitoba, Winnipeg (CA)

(72) Inventors: Sanjiv Dhingra, Winnipeg (CA); Alireza Rafieerad, Winnipeg (CA)

(21) Appl. No.: 18/555,761

(22) PCT Filed: Apr. 25, 2022
(86) PCT No.: PCT/CA2022/050628

§ 371 Date: Oct. 17, 2023

Related U.S. Application Data
(60) Provisional application No. 63/182,100, filed on Apr. 30, 2021.

(51) Int. Cl. C01B 32/914; C01B 21/06; C01G 35/00; H01G 11/46

(52) U.S. Cl. CPC C01B 32/914; C01B 21/0617; C01G 35/00; H01G 11/46; C01P 2002/85; C01P 2004/03; C01P 2004/04; C01P 2006/40

(57) ABSTRACT

A new fluorine-free tantalum carbide MXene-tantalum oxides (TTO) nanostructure was developed as a biocompatible electrode material for size-sensitive applications. The TTO hybrid structure is biocompatible with different types of human cells, and offers excellent volumetric capacitance, energy density, power density, and cyclability when assembled into a symmetric supercapacitor. The TTO offers high promise for future biomedical energy storage devices.

### PRIOR APPLICATION INFORMATION

The instant application claims the benefit of U.S. Provisional Patent Application Ser. No. 63/182,100, filed Apr. 30, 2021 and entitled “Development of Fluorine-Free Tantalum Carbide MXene Hybrid Structure as a Biocompatible Material for Supercapacitor Electrodes”, the entire contents of which are incorporated herein by reference for all purposes.

### BACKGROUND OF THE INVENTION

With ongoing rapid development in the area of bioelectronics, small and light weight biocompatible electrodes are in high demand for biomedical implantable devices such as cardiac pacemakers, neurostimulators and cochlear implants [1-5]. The supercapacitors (SCs) with promising properties, such as high power density, unlimited cycle life, eco-friendliness, and low-temperature charging ability, can become the ideal energy storage devices for medical electronics. Furthermore, implantable SCs can also be used for monitoring biological and electrophysiological information inside the human and mammalian body. Therefore, an ideal SC should be biocompatible, miniature in size, and it should possess high energy and power densities. Additionally, the electrochemical stability of biocompatible SC-based systems under physiological conditions is another advantage. However, current SCs consisting of biocompatible electrode materials are not able to meet all the aforementioned requirements in a single package. To date, several studies have reported the fabrication of biocompatible energy storage devices using advanced carbon-based materials such as graphene nanosheets, carbon nanotubes and fibers with a focus on maximizing the electric double layer capacitive properties [6-8]. However, bioelectrical applications of these materials are limited in terms of the energy surface support including low energy density per unit volume or mass [9]. It is important to further note that these anisotropic carbon structures implicate decreased biocompatibility in terms of cellular growth, proliferation and differentiation [10].

In this regard, recently reported two-dimensional (2D) transition metal carbides and nitrides (MXenes) are considered among booming materials because of their application in multiple fields [11-14]. The main energy-storage characteristics of the MXene nanosheets are excellent volumetric capacitance and energy density, which are vital for size-sensitive applications. MXene materials possess hydrophilic surfaces and are selectively etched from their MAX phase structures, where “M” represents one of the early transition metals (e.g., titanium, tantalum, niobium, or zirconium), “A” denotes one of the A-group elements (e.g., aluminum, silicon, or phosphorus) and “X” denotes either carbon or nitrogen. MXene structures possess tremendous physicochemical, electrical, optical and biological properties which have enabled them to be exquisitely used in various electrical and biological applications [15-17]. Given this, MXene is a suitable class of material for preparing electrodes for energy storage due to its superior metallic conductivity, electrochemical stability and higher volumetric capacitance compared to the conventional carbon-based electrode materials [13,18]. In previous studies, the exfoliation of different forms of MXene such as titanium carbide (Ti₃C₂Tₓ) and niobium carbide (Nb₂CTₓ) has been reported for application in lithium-ion (Li-ion) batteries, capacitors and regenerative medicine.[19-21] Recently, a new composition of MXene nanosheets, tantalum carbide (Ta₄C₃Tₓ) has been reported.[22,23] Tantalum (Ta)-based materials are well-known due to their excellent bio-functionality when compared to other MXene counterparts such as titanium (Ti)- and niobium (Nb)-based composites [24-27]. Moreover, the physical properties of Ta, including density, electrical conductivity and mechanical Young's modulus are higher in comparison to Ti and Nb. In fact, the exfoliated tantalum carbide MXene nanosheets have been recently reported as efficient nanoplatforms for cancer therapy [28]. However, in most of the MXene based previous reports, hydrofluoric acid (HF) was used as an etchant to remove aluminium (Al) from the MAX phase. Unfortunately, HF is highly corrosive and causes significant burns and toxicity upon contact, ingestion, or inhalation. More importantly, it leads to the formation of fluorine bonds in the end product that substantially decreases the electrochemical activity of MXene-based electrodes. Additionally, the application of fluorine-containing etchants leads to interaction between the remaining Al from the MAX phase structure and inert fluorine terminals, which is environmentally harmful during application of MXene-based materials. Therefore, fluorine containing etchants could potentially decrease the biocompatibility and volumetric capacitance properties of MXene-based energy storage electrodes.

Furthermore, functionalization of oxygen groups in the structure of 2D MXene nanosheets is reported to enhance the electrochemical performance of the composite [18]. The available literature on oxidized Ti₃C₂Tₓ and Nb₂CTₓ MXene composites revealed that the formation of crystalline transition metal oxide particles up to a few hundred nanometers in size enhanced the surface activity of nanosheets [13,29,30]. Therefore, it is conceptualized that the formation of oxygen-containing functional groups on the surface of Ta₄C₃Tₓ will promote its electrochemical properties when used as supercapacitor electrode. Furthermore, growth of metal oxide crystals on the surface of MXene prevents restacking of exfoliated MXene due to Van der Waals interaction; therefore, functionalization of oxygen-containing groups preserves the electrochemical performance of delaminated MXene.

In the current study, we present, for the first time, oxidized fluorine-free exfoliation of tantalum carbide MAX phase to synthesize a new Ta₄C₃Tₓ MXene-tantalum oxide (TTO) hybrid structure. Our study demonstrates that TTO can be used as a bioelectrode material for long-term supercapacitor applications. This new electrode has long-term electrochemical stability, excellent volumetric capacitance, and high energy/power densities and charging rate. Our findings confirm that the TTO hybrid structure is highly biocompatible with different human cell types. The energy density of the TTO electrode outperforms almost all the existing biomaterial-based electrodes. In addition, volumetric capacitance of the TTO is significantly higher than the majority of previously reported organic/inorganic biocompatible electrodes. This novel TTO nanostructure may act as a favourite electrode material for future applications in size-sensitive biomedical energy storage devices such as cardiac pacemakers, neurostimulators and cochlear implants.

### SUMMARY OF THE INVENTION

According to a first aspect of the invention, there is provided a method for synthesizing a two-dimensional transition metal carbides and nitrides (MXenes)-oxide hybrid structure material comprising:
(a) providing a quantity of a MAX phase powder, where “M” represents an early transition metal, “A” represents an A group element and “X” represents carbon or nitrogen;
(b) chlorinating the MAX phase powder, thereby solubilizing the A group element and forming a chlorinated MX powder;
(c) etching the chlorinated MX powder with an oxide source, thereby forming an exfoliated nanocomposite; and
(d) heating the exfoliated nanocomposite, thereby forming the MXenes-M-oxide hybrid structure material.

### BRIEF DESCRIPTION OF THE DRAWINGS

FIG. 1: Schematic model and stoichiometry of TTO hybrid structure. Illustration of (a) step-by-step schematic and (b) mechanism of reaction for the fluorine-free conversion of the Ta₄AlC₃ MAX phase to surface-modified Ta₄C₃Tₓ MXene nanosheets decorated with tantalum oxide nanoparticles.

FIG. 2: Morphology and microstructural characterization of the synthesized TTO hybrid structure. Scanning electron microscopic (SEM) images of the functionalized (a) Ta₄C₃Tₓ MXene and (b) TTO nanostructure samples after heat treatment at 220° C. for 2 hours. Field-emission SEM observations of TTO hybrid structure reveal effective delamination of layers, anchored by a tantalum oxide particle array. (c-d) The thermal treatment further improved the oxidization of Ta₄C₃Tₓ MXene layers. TEM images of the oxidized Ta₄C₃Tₓ MXene (c, and inset) and TTO (d, and inset) composites. The images show successful organization of TTO hybrid structures. The thermal treatment led to further improvement and well-defined distribution of Ta-oxide nanoparticles. High-resolution TEM images confirmed the presence of two different lattices with d-spacing of 0.261 nm and 0.338 nm, which is attributed to Ta₄C₃Tₓ MXene layers and tantalum oxide composites. (e) XPS narrow scan spectra of Ta 4f, O 1s, Al 2p corresponding to Ta₄AlC₃ MAX phase and oxidized TTO samples after thermal treatment at 220° C. for 2 hours, confirming proper extraction of Al from the MAX phase structure with effective exfoliation of MXene nanosheets. The XPS fittings further demonstrate that exfoliated Ta₄C₃Tₓ MXene sheets were successfully composited with Ta₂O₅—TaO₂ particles.

FIG. 3: Specific surface area measurement using Brunauer-Emmett-Teller analysis. (a) N₂ adsorption-desorption isotherm curves of the Ta₄AlC₃ MAX phase, oxidized Ta₄C₃Tₓ MXene, and TTO hybrid structure. The BET data depicted that specific surface area of the materials was 1.29 m²g⁻¹, 41.79 m² g⁻¹, and 51.02 m² g⁻¹ respectively. (b) Pore size distribution of the MAX phase, oxidized MXene, and TTO hybrid structure. As shown, the average pore diameter of the MAX phase was decreased about 4-folds in TTO nanostructure.

FIG. 4: Electrical and electrochemical measurements of fabricated TTO hybrid structure electrode. (a) Cyclic voltammetry curves of the oxidized Ta₄C₃Tₓ MXene electrode and (b) TTO hybrid structure electrode at different scan rates in PVA/H₃PO₄ solid electrolyte after 10,000 cycles of the two-electrode experiment. (c) The galvanostatic charge/discharge (GCD) curves of the oxidized Ta₄C₃Tₓ MXene electrode and (d) the TTO hybrid structure electrode. (e) Specific capacitance for both electrodes and volumetric capacitance of TTO hybrid structure electrode at different scan rates and (f) different specific currents. (g) The Nyquist plot of the oxidized Ta₄C₃Tₓ MXene electrode and TTO hybrid structure electrode. The inset shows the electrical equivalent circuit. (h) CV curve of the TTO hybrid structure electrode at 100 mV s⁻¹. The pink and blue areas show the direct contributions of the capacitive and diffusion mechanisms respectively. (i) Capacity contribution from capacitive and diffusion-controlled kinetic processes at different scan rates for the TTO hybrid structure electrodes.

FIG. 5: Comparison of TTO supercapacitor with some of the previously reported organic and inorganic electrode materials. (a) Ragone plots comparing the performance of TTO with electrical double layer (EDL) capacitors (35 and 50 mF, 300 μF/3 V), graphene oxide modified protein electrode supercapacitor, aluminum electrolytic capacitor (12 μA h/3.3 V) and Lithium-ion thin film battery (LiTF, 500 μA h/5 V).^{[45-52]} Energy density/power density of the TTO is significantly higher than above-mentioned electrodes. (b) Ragone plots comparing energy and power densities of the TTO hybrid structure supercapacitor to PANI/Ti₃C₂Tₓ [42], RuO₂/MXene yarn [43], Mo_{1.33}C/PEDOT:PSS [43] Ti₃C₂Tₓ/RGO [53], and MXene/NiCo-LDHs [54]. (c) Supercapacitor cycling stability, volumetric capacitance retention and charge-discharge cycle at a current density of 1 Ag⁻¹. (d) The image shows an LED powered by the TTO supercapacitor electrodes. Zoom-view panel shows the schematic view of TTO-based solid-state supercapacitor containing PVA/H₃PO₄ gel electrolyte. The picture demonstrates that TTO supercapacitor was able to successfully power the LED.

FIG. 6: Assessment of biocompatibility of the Ta₄AlC₃ MAX phase and Ta₄C₃Tₓ MXene-tantalum oxides materials with human cells. (a) The MAX phase, oxidized Ta₄C₃Tₓ, and TTO materials were co-cultured with human iPSC-derived-fibroblasts, cardiomyocytes, and neural progenitor cells (NPCs) for 24 hours. WST-1 proliferation assay was performed to evaluate cytocompatibility of materials. Our data demonstrate that MXene was compatible with all three cell types, as co-culture with biomaterial did not affect cellular proliferation compared to control group. (b) Cytotoxicity evaluation of the MAX phase, oxidized Ta₄C₃Tₓ, and TTO hybrid structure was assessed by LDH release after co-culturing with human MSC for 24 hours. LDH data show no significant difference among different MXene groups and the control group. (c) LIVE/DEAD assay was performed using the fluorescent dye to assess biocompatibility of human MSC with the material. After co-culture with different forms of MXene, MSC were stained with Calcein (for live cells, green) and EthD-1 (for dead cells, red). Images were captured using Nikon Ti-2 fluorescent microscope. No significant difference in viability between different groups was detected. (n=3-4 per group). (“ns”=statistically no significant difference, *=p<0.05 and **=p<0.01).

### DESCRIPTION OF THE PREFERRED EMBODIMENTS

Unless defined otherwise, all technical and scientific terms used herein have the same meaning as commonly understood by one of ordinary skill in the art to which the invention belongs. Although any methods and materials similar or equivalent to those described herein can be used in the practice or testing of the present invention, the preferred methods and materials are now described. All publications mentioned hereunder are incorporated herein by reference.

Application of nontoxic two-dimensional transition-metal carbides (MXenes) has recently gained ground in bioelectronics. In group-4 transition metals, tantalum possesses enhanced biological and physical properties compared to other MXene counterparts. However, the application of tantalum carbide for bioelectrodes has not yet been explored. Here, we demonstrate fluorine-free exfoliation and functionalization of tantalum carbide MAX-phase to synthesize a novel Ta₄C₃Tₓ MXene-tantalum oxide (TTO) hybrid structure through an innovative, facile and inexpensive protocol. Additionally, we report the application of TTO composite as an efficient biocompatible material for supercapacitor electrodes. The TTO electrode displays long-term stability over 10,000 cycles with capacitance retention of over 90% and volumetric capacitance of 447 F cm⁻³ (194 F g⁻¹) at 1 mV s⁻¹. Furthermore, TTO shows excellent biocompatibility with human-induced pluripotent stem cells-derived cardiomyocytes, neural progenitor cells, fibroblasts, and mesenchymal stem cells. More importantly, the electrochemical data show that TTO outperforms most of the previously reported biomaterials-based supercapacitors in terms of gravimetric/volumetric energy and power densities. Therefore, TTO hybrid structure may open a gateway as a bioelectrode material with high energy-storage performance for size-sensitive applications such as cardiac pacemakers, neurostimulators and cochlear implants.

According to an aspect of the invention, there is provided a method for synthesizing a two-dimensional transition metal carbides and nitrides (MXenes)-oxide hybrid structure material comprising:
(a) providing a quantity of a MAX phase powder, where “M” represents an early transition metal, “A” represents an A group element and “X” represents carbon or nitrogen;
(b) chlorinating the MAX phase powder, thereby solubilizing the A group element and forming a chlorinated MX powder;
(c) etching the chlorinated MX powder with an oxide source, thereby forming an exfoliated nanocomposite; and
(d) heating the exfoliated nanocomposite, thereby forming the MXenes-M-oxide hybrid structure material.

The MAX phase powder may be any suitable MAX phase powder known in the art, for example but by no means limited to the group consisting of tantalum aluminium carbide (Ta₄AlC₃), vanadium aluminium carbide (V4AlC₃), niobium aluminium carbide (Nb₂AlC₃ and Nb₂AlC), titanium aluminium carbide (Ti₃AlC₂), zirconium aluminium carbide (Zr₂AlC), and hafnium aluminium carbide (Hf₃AlC₂).

In some embodiments of the invention, the MAX phase powder is tantalum carbide.

The MAX phase powder may be chlorinated using any suitable chlorination method known in the art, for example but by no means limited to, HCl and/or HClO.

In some embodiments of the invention, the MAX phase powder is chlorinated by treatment with HCl, for example, with 6M HCl.

The oxide source may be any suitable oxide source known in the art, for example but by no means limited to KOH, NaOH, H₂O₂ and/or LiOH.

In some embodiments of the invention, the oxide source is KOH.

The exfoliated nanocomposite may be heated at a temperature between from about 200 to about 500 C, for a time period of from about 2 to about 4 hrs. In some embodiments, the exfoliated nanocomposite may be heated at about 220C for about 2 hrs, wherein “about” indicates plus/minus 10%.

According to another aspect of the invention, there is provided a MXenes-oxide hybrid structure material prepared according to the above-described method.

In some embodiments of the invention, the MXenes-oxide hybrid structure material is used in a bioelectrode material.

In some embodiments of the invention, the MXenes-oxide hybrid structure material is used in a supercapacitor electrode.

This study reported the first fluorine-free synthesis and application of Ta₄C₃Tₓ MXene-tantalum oxides hybrid structure material for energy storage applications. The TTO-based electrode showed excellent volumetric capacitance compared to previously reported biocompatible electrodes. Furthermore, the TTO hybrid structure is highly biocompatible with different types of human cells, which is highly beneficial for future applications in bioelectronics and biosensors. Finally, when assembled into a symmetric supercapacitor, the TTO hybrid structure material possessed high energy/power densities and long-term cyclability. The stability of TTO electrodes was estimated to be over 10,000 cycles.

The invention will now be further explained and/or elucidated by way of examples; however, the invention is not necessarily limited to or by the examples.

### Example 1—Fabrication of TTO Hybrid Structure

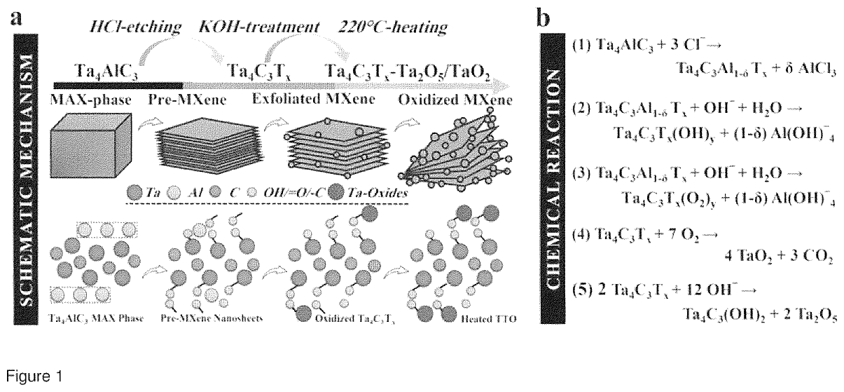

Specifically, we employed an innovative fluorine-free etching method to prepare TTO hybrid nanostructure from raw and bulk material. Recently, application of an alkaline-induced method for removal of Al from the Ti₃AlC₂ MAX phase to synthesize Ti₃C₂Tₓ MXene was reported [31]. However, the main challenge in etching the Al layer from MAX phase in alkaline media is the blocked/slow kinetic reactions due to the formation of unwanted oxide/hydroxide layers on the MXene surface [32]. To address this, we utilized our innovative alkaline-based etching method to prepare the TTO via a two-step acidic/alkaline (HCl/KOH) treatment. Briefly, Ta₄AlC₃ MAX phase powder was treated sequentially with 6M hydrochloric acid (HCl) solution and 6M potassium hydroxide (KOH) solution to synthesize an exfoliated nanocomposite. This led to formation of multilayered oxidized Ta₄C₃Tₓ nanosheets anchored with Ta-oxide particles. These were subsequently subjected to thermal treatment at 220° C. under moderate air heating for further functionalization and oxidation, resulting in the formation of final TTO hybrid structure. The step-by-step schematic model for the synthesis and functionalization of the mixed-dimensional TTO nanocomposite is shown in FIG. 1a.

In our proposed mechanism of reaction (FIG. 1b), the Al-atoms on the edge and outer surface of Ta₄AlC₃ MAX phase were rapidly chlorinated using HCl through the production of soluble aluminum chloride (AlCl₃) [31]. Therefore, a considerable amount of surface Al atoms are thought to be removed during this step. Subsequent etching treatment in KOH solution further led to lower levels of insoluble aluminum hydroxide [Al(OH)₃] and aluminum oxide hydroxide [AlO(OH)] on the surface of the material when compared to the classic alkaline protocol. The lattice-like features of the Ta-layers limit the transformation of insoluble Al-based compounds to soluble aluminate [Al(OH)₄⁻] [31,32]. However, the hybrid protocol employed in this study allows continued exfoliation and secondary crystal nucleation of the tantalum carbide material to give rise to oxidized Ta₄C₃Tₓ MXene nanosheets. Furthermore, ongoing oxidation of exposed inner Al and Ta atoms by OH resulted in a higher degree of functionalization with —OH and ═O groups.

### Example 2—Characterization of TTO Hybrid Structure

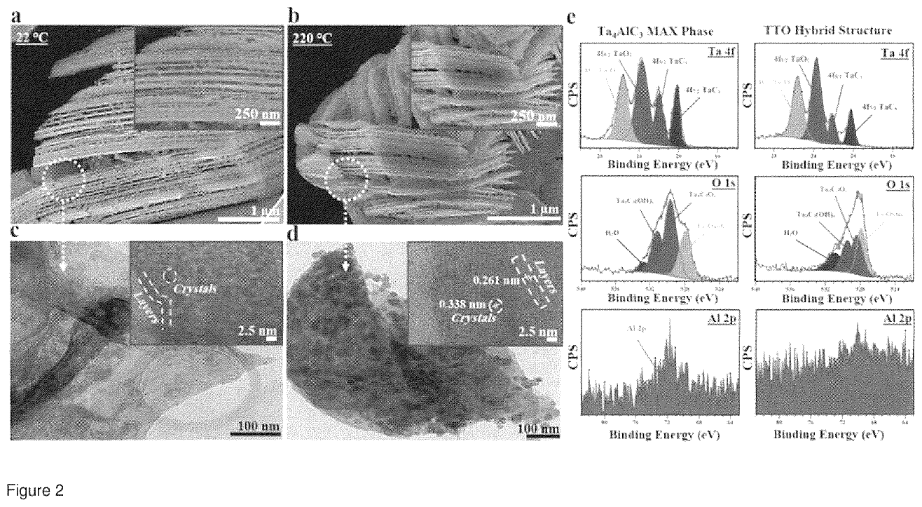

The scanning electron microscopic (SEM) images of the functionalized Ta₄C₃Tₓ MXene nanosheets prior to thermal treatment are presented in FIG. 2a. The well-exfoliated MXene nanosheets are strewn with a considerable number of tantalum oxide nanoparticle clusters. Subsequent thermal treatment at 220° C. for 2 hours led to significantly enhanced exfoliation and functionalization of MXene nanosheets with Ta-oxide nanoparticles, which is described here as a Ta₄C₃Tₓ MXene-Tantalum Oxide (TTO) hybrid structure (FIG. 2b). Specifically, FIGS. 2a and 2b show scanning electron microscopic (SEM) images of the synthesized TTO hybrid structure before heat treatment (22° C.) and after heat treatment at 220° C. for 2 hours. As will be apparent to those of skill in the art, these figures demonstrate effective synthesis of multi-layered MXene nanosheets, anchored by tantalum oxide particles.

Furthermore, field-emission SEM images of the oxidized Ta₄C₃Tₓ MXene and TTO hybrid structure revealed a slight decrease in the wall-to-wall interlayer space of MXene nanosheets after thermal treatment.

The high-resolution transmission electron microscopy (TEM) of oxidized Ta₄C₃Tₓ MXene and the TTO hybrid structure revealed that individual nanoparticles are approximately 5 nm in diameter and cluster to form larger decorations seen in the SEM images (FIGS. 2c and 2d). These statements provide further characterization of the morphology (diameter and lattice) of each particle. The fast Fourier transform (FFT) analysis of TTO hybrid structure showed d-spacing lattices of 0.261 nm and 0.368 nm, corresponding to oxidized Ta₄C₃Tₓ MXene and tantalum oxide (Ta₂O₅) crystals respectively (FIG. 2d and inset). These lattice parameters are in good agreement with previously reported literature on stable Ta₄C₃Tₓ MXene and Ta₂O₅ [28,33-35]. This FFT analysis is also congruent with published literature on the coexistence of bulky tantalum carbide (TaC) and Ta₂O₅, which reported lattice spacing of approximately 0.26 nm and 0.38 nm, corresponding to the TaC (111) and Ta₂O₅ (001) planes respectively [33-35]. These statements confirm the crystalline nature of the synthesized material.]

The selected area electron diffraction (SAED) patterns of TTO hybrid structure displayed a higher degree of crystalline structure with well-defined hexagonal planes compared to oxidized Ta₄AlC₃ MXene samples. Together these observations provide robust evidence that the innovative fluorine-free exfoliation and functionalization protocol employed in the current study has worked successfully to synthesize TTO nanostructure from the Ta₄AlC₃ MAX phase.

The physicochemical properties of materials were further evaluated by X-ray photoelectron spectroscopy (XPS), energy-dispersive X-ray spectroscopy (EDS), SAED, and X-ray diffraction (XRD) analysis. XPS was used to characterize the structural transformation of TaAlC₃ MAX phase to oxidized Ta₄C₃Tₓ MXene and TTO hybrid structure. Comparison of survey spectra showed a significant change in the elemental composition of materials during the synthesis process. In particular, characteristic Al 2p peaks of TaAlC₃ MAX phase were significantly decreased in the TTO hybrid structure. High resolution XPS spectra of TTO hybrid structure showed well-defined characteristics of Ta₄C₃Tₓ MXene. A comparison between Al 2p spectra of the Ta₄AlC₃ MAX phase and TTO confirmed effective elimination of Al layer, with more than 84% of elemental Al removed during the hybrid synthesis process (FIG. 2e). This degree of exfoliation is highly comparable with the widely-used HF etching method for exfoliation [22]. This is confirmed by the spectra of Ta 4f, which revealed two main peaks of TaC (4f 5/2 and 4f 7/2) at binding energies of 18 and 24 eV attributed to exfoliated Ta₄C₃Tₓ MXene nanosheets.

As is known to those of skill in the art, HF is known to be an effective etchant to synthesize MXene nanosheets from bulk materials. However, the toxicity of HF limits the biomedical applications of MXene products synthesized using HF. In contrast, HCl is a milder acid, but, despite this, the results that we obtained with our innovative and facile method that employed HCl—KOH for etching of MAX phase to synthesize TTO, were surprisingly comparable with what has been reported with HF. Therefore, we were pleasantly surprised with the outcome as the process described herein avoids the complexities associated with the handling of HF while producing a comparable product that has the significant advantage of being biocompatible.

The Ta 4f, O Is, and C Is spectra demonstrated a change in the degree of exfoliation and functionalization when converting Ta₄AlC₃ MAX phase to TTO hybrid structure (FIG. 2e). Ta₄C₃Oₓ decreased from 41.7% to 27.6%, and Ta₄C₃(OH), increased from 30.8% to 31.6%. Additionally, these spectra revealed an approximately 20% decrease in the surface atomic ratio of Ta—C bonds and an increase of 10.43% in the surface atomic ratio of Ta—O bonds in the TTO hybrid structure. The TTO hybrid structure contains two lateral species of Ta⁴⁺ and Ta⁵⁺ as the main tantalum oxide crystals of Ta₂O₅ and TaO₂ at the binding energy of 22 to 27 eV in the Ta 4f spectrum. Taken together, these findings confirm the formation of tantalum oxide during the synthetic process.

Finally, the successful synthesis of TTO hybrid structure using the fluorine-free process was further corroborated by EDS and XRD. The EDS elemental analysis demonstrated successful extraction of Al from the structure of Ta₄AlC₃ MAX phase with a decrease in the atomic percentage of Al from 20.57% to 11.31%. The average weight percentage of Al similarly decreased from 12.64% to 4.43%. Concurrently, the atomic percentage of oxygen increased from 20.03% to 30.05%. The histogram also confirmed the absence of F, Cl, and K in the final composition of the TTO hybrid structure. Specifically, as can be seen, the Al percentage has been reduced significantly, down to acceptable levels.

The XRD pattern of the Ta₄AlC₃ bulk material was typical with standard peaks at their expected 2θ values [22]. In agreement with the previous observations, peaks originating from the aluminum-containing MAX phase were significantly decreased after fluorine-free etching and exfoliation by the HCl/KOH process. One of the Ta₄AlC₃ peaks at around 16.5° 20 was entirely removed in the TTO hybrid structure. Additionally a minor contamination peak ascribed to Ta₂C with the reflection at 2θ˜50° was absent in the XRD spectrum of TTO hybrid structure [36]. Furthermore, a newly emerged (002) peak at around 7° 2θ corresponds to an aluminum-etched tantalum carbide-tantalum oxide material with the enlarged lattice parameters. Additional downshifts are also observed in the XRD spectra of the TTO hybrid structure due to increased carbon lattice spacing after the acid/alkaline treatment. Lastly, characteristic small peaks corresponding to tantalum oxide particles anchored on the MXene surface were also observed in the structure of the TTO. Together these findings support the successful synthesis and functionalization of layered TTO hybrid structure using a fluorine-free exfoliation and functionalization protocol.

### Example 3—Specific Surface Area of TTO Hybrid Structure

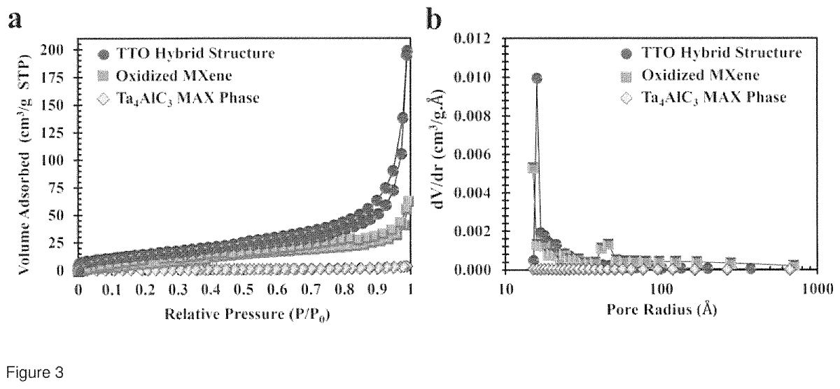

The surface area of carbon-based nanomaterials is an important determinant of their electrochemical properties. The specific surface area of Ta₄AlC₃ MAX phase, oxidized Ta₄C₃Tₓ MXene, and TTO hybrid structure was determined using Brunauer-Emmett-Teller (BET) nitrogen adsorption isotherms (FIG. 3a). The specific surface area of Ta₄AlC₃ MAX phase, oxidized Ta₄C₃Tₓ MXene, and TTO hybrid structures were 1.29 m² g⁻¹, 41.79 m² g⁻¹, and 51.02 m² g⁻¹ respectively. There was a 40-fold increase (approximately) in the surface area from Ta₄AlC₃ MAX phase to oxidized Ta₄C₃Tₓ MXene, which is a result of Al etching and formation of a porous MXene structure.^{[37-39]} The specific surface area of the TTO hybrid structure is approximately 20% higher than that of the oxidized Ta₄C₃Tₓ MXene and can be attributed to higher levels of Ta-oxide nanoparticles on the surface of the oxidized MXene material. As is known by those of skill in the art, the specific surface area of any nanomaterial is a very important parameter for defining its energy storage abilities and electrical properties. Therefore, surface area basically defines performance of any energy storage material. This high surface area can be readily detected by assessing the optical properties of the TTO hybrid structure. The aqueous suspension of TTO hybrid structure (50 μg mL⁻¹) exhibited high degrees of autofluorescence at several wavelengths across the visible spectrum.

Consistent with Barrett-Joyner-Halenda (BJH) theory, the total pore volume was increased by approximately 14-fold in the TTO hybrid structure when compared with Ta₄AlC₃ MAX phase. The average pore diameter, however, decreased from 81.15 nm in Ta₄AlC₃ MAX phase to 32.25 nm in oxidized Ta₄C₃Tₓ MXene and 24.42 nm in TTO hybrid structure (FIG. 3b). The dramatic increase in specific surface area during the synthesis process can thus be explained by a significant increase in the overall porosity of the TTO hybrid structure through formation of new micro- and mesopores during the hybrid acid/alkali and thermal treatments. Specifically, the increase in porosity that we observed in the final product is responsible for increase in specific surface area.

### Example 4—Electrochemical Properties of TTO Hybrid Electrode

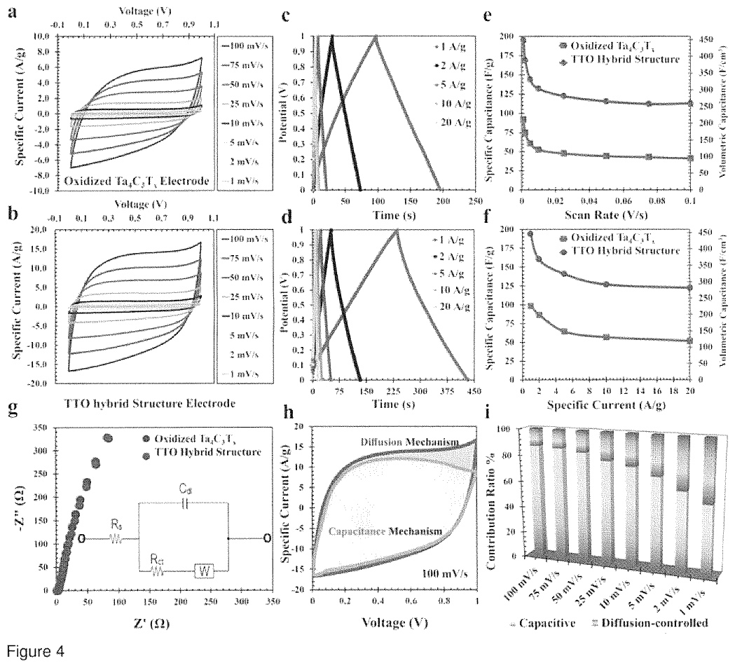

The electrochemical properties of the TTO hybrid structure were characterized by two-electrode system. The TTO hybrid structure and oxidized Ta₄C₃Tₓ MXene based electrodes were fabricated using a 8:1:2 weight ratio of MXene material, Super P carbon black and polyvinylidene fluoride (PVDF). The cyclic voltammetry (CV) and galvanostatic charge/discharge (GCD) were measured in the presence of a polyvinyl alcohol/phosphoric acid (PVA/H₃PO₄) solid electrolyte. The CV profiles of the oxidized Ta₄C₃Tₓ MXene electrode and the TTO hybrid structure electrode were quasi-rectangular at scan rates ranging from 1 to 100 mV s⁻¹ with near mirror symmetry among all CV profiles, indicating that the majority of capacitance is associated with the electric double layer capacitance (EDLC) mechanism (FIGS. 4a and 4b). Additionally, GCD curves of the oxidized Ta₄C₃Tₓ MXene electrode and the TTO hybrid structure electrode feature nearly triangular shapes with extremely low internal resistance at the beginning of the discharge curve (FIGS. 4c and 4d). This reflects the pseudocapacitive nature of the oxidized MXene and TTO hybrid structure electrodes.[40] In particular, the TTO hybrid structure exhibited significantly greater capacitance when compared with the oxidized Ta₄C₃Tₓ MXene material. The observed specific capacitance values for TTO were more than 2-fold higher than oxidized Ta₄C₃Tₓ MXene material at the same scan rate or specific current (FIGS. 4e and 4f). In fact, the new TTO hybrid structure electrode showed higher volumetric capacitance than most of the recently reported biomaterials-based electrodes.

The electrochemical impedance spectroscopy (EIS) analysis was used to investigate the ion-diffusion/transport resistance of the TTO electrode in the frequency range of 0.01 Hz to 200 kHz at open-circuit-potential (OCP) measurements. The impedance spectra of the oxidized Ta₄C₃Tₓ MXene electrode and the TTO electrode form a small arc and a spike at the higher and lower frequency regions respectively. The TTO hybrid structure electrode clearly showed lower electrolyte resistance than the oxidized Ta₄C₃Tₓ MXene electrode (FIG. 4g). This may be due to the higher concentration of tantalum oxide nanoparticles on the surface of the TTO. As a result, in the equivalent electrical circuit model of the TTO hybrid structure electrode, there is a Warburg impedance element (W) representing linear diffusion under semi-infinite conditions. As will be apparent to one of skill in the art, this describes the electrical properties of our electrode material. Furthermore, the solution resistance (Rₛ) signifies the electrolyte resistance and a constant phase-element (C_{dl}) obtained by EDLC of the TTO (FIG. 4g and inset).

The electrochemical mechanism measurements of TTO hybrid structure were further investigated based on the following equation:

$$i = {k}_{1} v + {k}_{2} {v}^{1 / 2} \qquad Equation ( 1 )$$

This equation includes two scan rate-related terms at a fixed scan rate and potential. The k₁v term is attributed to the current density contributed by the fast-kinetics process in both electric double-layer capacitance and Faraday pseudocapacitance [4]. The k₂v^{1/2} term is related to the current density contributed by a slow diffusion-controlled process [41]. Both constants, k₁ and k₂ are obtained from a different form of the above equation in a log-log plot, as shown below.

$$i / {v}^{1 / 2} = {k}_{1} {v}^{1 / 2} + {k}_{2} \qquad Equation ( 2 )$$

The contribution of the fast-kinetics process for various sweep rates is shown in FIGS. 4h and 4i. The decoupling result for the TTO hybrid structure electrode at 100 mV s⁻¹ offers a remarkable fast-kinetics contribution of 87.0% (FIG. 4h). These data confirm that the performance of the electrode material as a capacitor is very efficient. Furthermore, while the fast capacitance remained unaffected by scan rate, the contribution of slow capacitance increases at lower scan rates (FIG. 4i). This effect is attributable to the oxygen-containing terminal groups on the surface of the TTO hybrid structure, which facilitates electrochemical Faradaic reactions to result in a greater contribution of diffusion-controlled mechanisms at these lower scan rates.

These findings were confirmed with measurements from a three-electrode system using the same electrolyte against an Ag/AgCl reference electrode. The results further elucidated the pseudocapacitance effect of Ta₂O₅ and other oxygen-containing functional groups in acidic electrolytes. The TTO hybrid structure electrode exhibited electric double layer capacitance (EDLC) behavior with quasi-pseudocapacitance behavior. The oxidized surface of TTO may significantly increase the wettability and enlarge the ion-accessible surface area, facilitating rapid ion diffusion/transportation into the internal pores. The possible redox reaction of Ta₄C₃Tₓ MXene in an acidic medium is depicted in Equation 3 [42].

$$T {a}_{4} {C}_{3} {{O}_{x} ( O H )}_{y} + δ {H}^{+} + δ {e}^{-} ↔ T {a}_{4} {C}_{3} {{O}_{x - δ} ( O H )}_{y - δ} \qquad Equation ( 3 )$$

The possible redox reaction of Ta₂O₅ on Ta₄C₃Tₓ MXene in an acidic medium is shown in Equation 4 [43].

$$T {a}_{2} {O}_{5} + β {H}^{+} + {βe}^{-} ↔ {H}_{β} T {a}_{2} {O}_{5} \qquad Equation ( 4 )$$

The normalized capacitance value for the two-electrode system included contributions of two TTO hybrid structure electrodes, while the three-electrode system used a single TTO hybrid structure electrode. Therefore, the values derived from three-electrode measurements should be approximately two times of the values obtained from two-electrode measurements (FIG. 4e) [38]. Thus, the obtained results from the three-electrode and two-electrode systems of the TTO hybrid structure are in agreement with each other.

### Example 5—Ragone Plot of TTO Electrode Supercapacitor

Next, we wanted to evaluate and compare the performance of the TTO hybrid structure electrode with literature-reported organic/inorganic energy storage materials for bio-implantable applications. Ideally, the best bioelectrode materials for implantable supercapacitors should possess excellent energy and power density in a single product, while having low individual component toxicity in case of damage and uncontrolled failure. In particular, currently used lithium-ion batteries and their toxic electrolytes in cardiac pacemakers, neurostimulators, cochlear implants and spinal cord stimulators have been reported to seriously jeopardize patient safety in cases of premature failure [44,45].

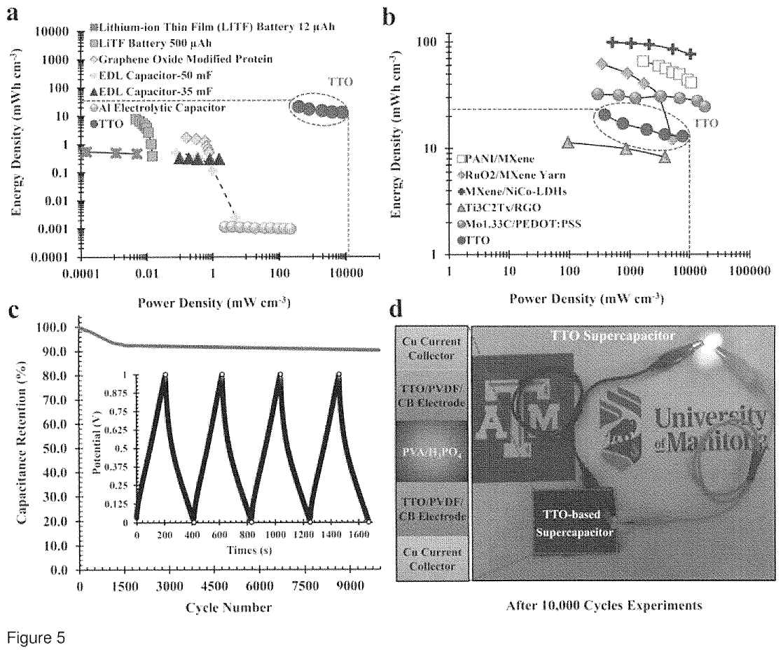

In the current study, Ragone plots are presented to compare the volumetric performance of the TTO hybrid structure supercapacitor with several previously-reported biocompatible supercapacitors and MXene-based electrode supercapacitors (FIGS. 5a and 5b). The TTO hybrid structure electrodes were packaged into a symmetric supercapacitor using copper current collectors and a PVA/H₃PO₄ solid electrolyte. Our data confirm that the TTO hybrid structure supercapacitor was superior to almost all other bioelectrode materials, including electric double layer (EDL) capacitors, biophilized graphene oxide modified protein electrode supercapacitor, aluminum electrolytic capacitors and lithium-ion thin film batteries (FIG. 5a) [46]. Additionally, the fluorine-free TTO supercapacitor has competitive energy and power densities with other previously published MXene-based supercapacitors (FIG. 5b). Importantly, its performance also exceeds that of many currently reported non-MXene carbon-based electrodes, including graphene/CNT nanocomposites (165 F cm⁻³) [47], graphene-based electrodes (260 F cm⁻³) [48], activated carbons (60-100 F cm⁻³) [49,50], and carbide-derived carbons (180 F cm⁻³) [51,52]. Finally, the TTO electrode possesses excellent areal efficiency when compared with other recently reported supercapacitor electrode materials.

In addition to its excellent capacitance properties, the TTO displayed outstanding long-term stability over 10,000 cycles with capacitance retention maintained over 90% of the initial performance (FIG. 5c). The capacitance retention was stabilized after 1,500 cycles, with only an additional 2.4% decrease in capacitance over the subsequent 8,500 cycles. Together, these data confirm that the TTO hybrid structure supercapacitor synthesized in the current study possesses long cycle stability, excellent volumetric capacitance and high charge/discharge rate performance. As a proof-of-concept, the energy storage performance of the TTO hybrid structure supercapacitor was functionally assessed by connecting it to a light-emitting diode (LED); the experiment demonstrated that the symmetric TTO was able to successfully power the LED (FIG. 5d).

### Example 6—Biocompatibility of TTO

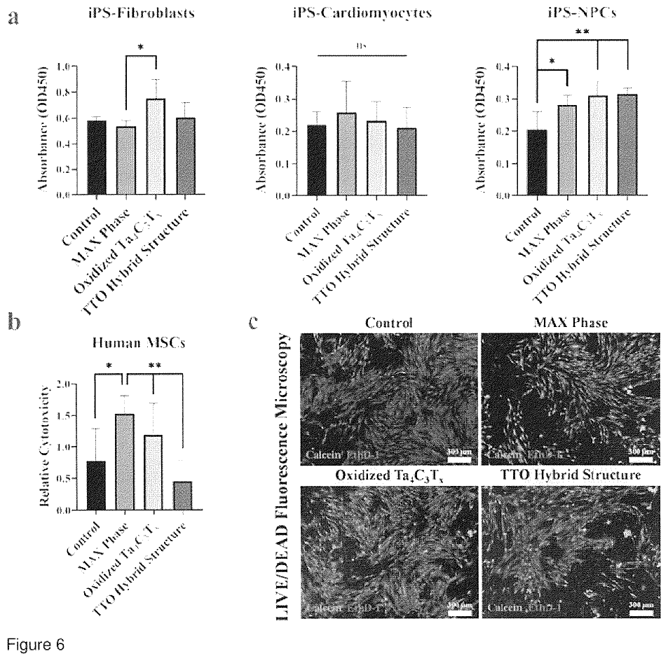

We also investigated the biocompatibility of oxidized TTO electrode with human induced pluripotent stem cells (hiPSC)-derived cardiomyocytes, neural progenitor cells, and fibroblasts. The hiPSC-derived cells were obtained using our established differentiation protocols [55]. When MXene-based materials (at a concentration 50 μg mL⁻¹) were co-cultured with these cells for 24 hours, assessment of cytotoxicity using the WST-1 assay showed that all forms of the Ta₄C₃Tₓ MXenes were compatible with cardiomyocytes, neural progenitor cells, and fibroblasts (FIG. 6a).

Additionally, TTO-based bio-electrodes may also be beneficial in the development and post-delivery monitoring of functional cell-based tissue constructs. Bone marrow-derived mesenchymal stem cells (MSC), a commonly used cell type in tissue engineering, were found to be biocompatible with all forms of Ta₄C₃Tₓ MXene-based samples used in this study. When co-cultured with materials for 72 hours, assessment of cytotoxicity by LDH assay showed excellent residual viability of cells in all groups as there were no significant differences in cytotoxicity between different MXene groups and the control group (FIG. 6b). On the other hand, MAX phase, due to the presence of Al, demonstrated lower biocompatibility to the cells. Representative images captured using a fluorescence-based live/dead assay also confirmed this finding (FIG. 6c). These data confirm that oxidized TTO electrode is biocompatible, and it can be used for implantable bioelectronic devices and tissue engineering applications.

### Example 7—Experimental Section

Fluorine-Free Synthesis of Oxidized Ta₄C₃Tₓ and TTO Hybrid Structure

Ta₄C₃Tₓ MXene nanosheets were partially exfoliated using hydrochloric acid (HCl). To do so, Ta₄AlC₃ MAX Phase powder was incubated in 6M solution of HCl in water at 37° C. for 72 hours in a shaking incubator at 260 rpm. The precipitates were collected after washing with ultrapure distilled water by spinning at 5,000 rpm for 5 minutes each. The precipitates were freeze dried for 48 hours and subsequently air dried at 60° C. The complete etching, exfoliation, and surface modification of the obtained material (dry powder) was achieved by treating it with potassium hydroxide (KOH, 6M) at room temperature for 90 hours. The edge exfoliation of specimens was obtained by centrifugation at 5,000 rpm followed by several washing steps and vacuum lyophilization (−80° C.& −54° C.) for 48 hours to avoid uncontrolled oxidization. The powder was then double-dried in an atmospheric oven at 50° C. for 48 hours. The resultant nanocomposite obtained at this step was labeled as oxidized Ta₄C₃Tₓ at room temperature (22° C.). For further functionalization and oxidation, the treated Ta₄C₃Tₓ nanosheets were subjected to thermal treatment at 220° C. for 2 hours under moderate air heating and labeled as TTO hybrid structure (220° C.).

### Physicochemical Characterization

The structural properties of materials were characterized using an FEI Nova NanoSEM 450 (Thermo Fisher Scientific), FEI Talos F200X S/TEM (Thermo Fisher Scientific), Thermo Nicolet Nexus 870, and Kratos Axis Ultra X-ray photoelectron spectroscopy (XPS) at the Manitoba Institute of Materials (MIM), University of Manitoba, Winnipeg, Canada. The SEM samples were mounted on pin stubs using carbon tape and coated with a gold-palladium (Au—Pd) coating to enable high magnifications. X-ray diffraction peaks of powdered samples were collected in the range from 5 to 80° 2-theta using continuous scan mode with a scan rate of 3º/minute and report interval of 0.05°. The measurement of specific surface area of the materials was determined by the Brunauer-Emmett-Teller (BET) analysis.

### Electrode Fabrication, Electrical and Electrochemical Measurements

The TTO electrodes were fabricated using the following procedures. Each TTO hybrid structure electrode was synthesized using 8:1:2 ratio of TTO hybrid structure (160 mg), Super P carbon black (20 mg) and PVDF (40 mg) in N-methyl-2-pyrrolidone (NMP) solvent. The slurry prepared by mixing these components was brushed on a carbon paper and pressed after drying in a vacuum oven at 70° C. for 24 hours. The capacitance properties of the prepared TTO electrodes were characterized by using two- and three electrode systems at room temperature.

Cyclic voltammetry and the constant current charge-discharge measurements were performed on Autolab electrochemical workstation (PGSTAT302 N model) and CH Instrument 640E Bipotentiostat. The specific capacitance for cyclic voltammetry-based measurement was calculated according to the following equation:

$$C = \frac{1}{2 v m Δ V} \int Id V \qquad Equation ( 5 )$$

where C, I, v, m, and ΔV are the specific capacitance, current, scan rate (V s⁻¹), weight of electrode, and scanning potential window respectively. The constant current charge-discharge test was performed for specific capacitance. Values were calculated using the following equation:

$$C = \frac{I Δ t}{m Δ V} \qquad Equation ( 6 )$$

where I, Δt, and ΔV are respectively discharge current, discharge time, and discharge potential window.^{[38]} The energy density and power density of the device were calculated as E=C(ΔV)^{2/}7.2 and P=3600 E/Δt, where E and P, are energy and power densities, respectively. Using the density of the packed electrolyte (2.3×10⁻³ kg cm⁻³), the volumetric energy density (Eᵥₒₗ) and volumetric power density (Pᵥₒₗ) were calculated using the following equations:

$${E}_{rol} ( Wh {cm}^{- 3} ) = E \cdot ρ \qquad Equation ( 7 )$$

$${P}_{rol} = 3600 \cdot \frac{{E}_{vol}}{Δ t} \qquad Equation ( 8 )$$

The CV and GCD measurements were performed with all solid-state two-electrode system in the presence of polyvinyl alcohol (PVA) and H₃PO₄ gel electrolyte. For this, a gel electrolyte solution was prepared by mixing 10 g of PVA and 10 g of H₃PO₄ in 100 mL of deionized water at 85° C. The solution was incubated in an oven at 40° C. for a week to solidify. A thin layer of the PVA/H₃PO₄ electrolyte was sandwiched between two active electrodes of the same size and mass and subjected to a hot-pressing step at 10.9 psi. The copper (Cu) foils were attached to the other side of the TTO electrode to be used as the current collector. For Ragone plots we used the total mass of the packaged TTO-based supercapacitor (959 mg) including TTO hybrid structure electrodes, electrolyte, carbon blacks, and PVDF to calculate and evaluate the total energy or power densities.

The capacitance of TTO-based electrodes was further characterized by using a three-electrode system at room temperature with phosphoric acid (H₃PO₄) solution as electrolyte. The platinum (Pt) and silver/silver chloride (Ag/AgCl) were used in the experiment as the counter electrode and the reference electrode, respectively.

### Density Measurement

The gravimetric capacitance of the Ta₄C₃Tₓ MXene/tantalum oxides (TTO) electrode is converted to volumetric capacitance by Archimedes' Principle. The density of TTO electrode was calculated using the following equation:

$$ρ = \frac{{W}_{a}}{{W}_{ax}} {ρ}_{ax} \qquad Equation ( 9 )$$

where Wₐ, Wₐₓ, ρ and ρₐₓ are the weight of the sample in air, weight of the sample in the auxiliary liquid of known density, the density of the sample and auxiliary liquid, respectively.

### Assessment of Energy Storage Performance of TTO Supercapacitor

The energy storage performance of TTO was assessed using a light-emitting diode (LED). The TTO electrode in the supercapacitor was charged and was connected in an LED output and the performance was observed.

### Induced Pluripotent Stem Cells Generation, Culture and Differentiation

Human induced pluripotent stem cells (hiPSCs) were generated from peripheral blood mononuclear cells (PBMC) isolated from human blood (collected from healthy individuals). All protocols were approved by the University of Manitoba Health Research Ethics Board (B2015:025, HS18974). To reprogram PBMCs toward iPSCs a commercial reprogramming kit CytoTune™-iPS 2.0 Sendai Reprogramming Kit was used (A16517, ThermoFisher Scientific, US). The detailed procedure is described in previously published studies [56,57].

The hiPSCs were cultured in TeSR™-E8™ (05990, STEMCELL Technologies) on Geltrex (A1413302, Gibco) and allowed to differentiate toward fibroblast, cardiomyocytes (CMs) and neural progenitor cells (NPCs) using our previously published protocols [55]. Briefly, embryoid bodies (EBs) were prepared in suspension in low attachment plates (174932, Thermo Scientific) and plated onto gelatin-coated plates on Day 8 (PMEF-CFL-P1, EMD Millipore). They were allowed to differentiate spontaneously toward fibroblasts, which were manually dissected from the culture plate and characterized by staining for HSP47 (ab77609, Abcam) and FSP (ab11333, Abcam). The cell populations were enriched over several passages to ensure a pure fibroblast population.

The hiPSCs were differentiated to cardiomyocytes using following protocol: iPSCs (>passage 20) were passaged onto Geltrex-coated plates using Versene Solution (15040066, Gibco) and grown till the cells reached ˜85% confluency. The medium was replaced with CDM3, consisting of RPMI 1640 (61870036, Gibco) supplemented with 500 μg mL⁻¹ recombinant human albumin (A9731, Sigma-Aldrich), and 213 μg mL⁻¹ L-ascorbic acid 2-phosphate (A8960, Sigma-Aldrich). The culture medium was replaced on alternate days (48 h). At days 0-2, the medium was supplemented with 6 μM of the glycogen synthase kinase 3-ß inhibitor CHIR99021 (SML1046, Sigma-Aldrich). On day 2, the medium was changed to CDM3 supplemented with 2 μM of the Wnt inhibitor-Wnt-C59 (5.00496.0001, CalBiochem). Day 4 onwards, the cells were cultured in medium without the inhibitors. The beating cells were observed from day 7. At day 10, medium was replaced with RPMI 1640 without glucose (11879020, Gibco), 500 μg mL⁻¹ recombinant human albumin, and 213 μg mL⁻¹ L-ascorbic acid 2-phosphate supplemented with 4 mM L-lactic acid (71720, Sigma-Aldrich) for metabolic enrichment of cardiomyocytes. The cardiomyocytes were characterized by immunofluorescence staining for sarcomeric alpha actin (ab9465, Abcam) and MYH6 (ab50967, Abcam).

The differentiation of iPSCs toward neural progenitor cells was carried out using EB method by initiating the treatment with the TGF-beta/Smad inhibitor SB 431542 (16-141, Torcis) for 2 days. The EBs were then plated on polyornithine-coated plates on day 5 (A004, Merck Millipore). The neural rosettes were visually identified at day 7-10. After that, the rosettes were excised and grown on polyornithine-coated plates in STEMPRO NSC SFM kit (A1050901, Gibco). The NPC characterization was carried out by immunostaining for NESTIN (sc-23927, Santa Cruz Biotechnology) and PAX6 (sc-81649, Santa Cruz Biotechnology).

### Human Mesenchymal Stem Cells Culture

Human bone marrow derived mesenchymal stem cells (MSC) were purchased from Lonza (PT 2501, CA10064-080) and cultured in low-glucose DMEM (10567014, Gibco) according to previously published protocols [58].

### Cell Proliferation Assay

Human iPSC-derived fibroblasts, cardiomyocytes and neural progenitor cells were plated on 96-well plates and co-cultured with or without the raw MAX phase and oxidized TTO composites at a concentration of 50 μg mL⁻¹ for 24 hours. Then, the cell proliferation was assessed using the WST-1 proliferation kit (K301, BioVision™).

### Assessment of Cytotoxicity

To assess cytotoxicity, human MSC were cultured with different forms of MXene for 24 hours at a concentration of 50 μg mL⁻¹. To evaluate cytotoxicity, LDH release from damaged cells (if any) was measured in the supernatant using a Cytotoxicity Detection Kit (MK401, Takara Bio).

### Assessment of Cellular Viability Using LIVE/DEAD™ Assay

To assess the effect of TTO MXene on cell viability, LIVE/DEAD™ assay was performed. Briefly, human MSC (2×10⁵) were plated on 96-well plates and co-cultured with or without the MAX phase and TTO composites for 72 hours. The cells were then stained using a LIVE/DEAD™ Viability/Cytotoxicity Kit (L3224, Invitrogen) for 30 min and then visualized using Nikon Eclipse Ti-2 fluorescence microscope. Calcein was detected using the GFP Filter (Ex480/Em535) and EthD-1 was detected using the TRITC Filter (Ex540/Em605).

### Statistical Analysis

Data were reported as mean±SD unless otherwise specified. Comparison of data between multiple groups was performed using one-way analysis of variance (ANOVA) followed by Tukey's post-hoc multiple comparison test, and analysis between two groups was made using Student's t-test (two-tailed). Statistical analysis was performed using GraphPad Prism 8.0.1 (San Diego, USA). Statistical significance was defined as p<0.05.

While the preferred embodiments of the invention have been described above, it will be recognized and understood that various modifications may be made therein, and the appended claims are intended to cover all such modifications which may fall within the spirit and scope of the invention.

### REFERENCES

[1] W. Gao, S. Emaminejad, H. Y. Y. Nyein, S. Challa, K. Chen, A. Peck, H. M. Fahad, H. Ota, H. Shiraki, D. Kiriya, D.-H. Lien, G. A. Brooks, R. W. Davis, A. Javey, Nature 2016, 529, 509.
[2] J. Kim, G. A. Salvatore, H. Araki, A. M. Chiarelli, Z. Xie, A. Banks, X. Sheng, Y. Liu, J. W. Lee, K.-I. Jang, S. Y. Heo, K. Cho, H. Luo, B. Zimmerman, J. Kim, L. Yan, X. Feng, S. Xu, M. Fabiani, G. Gratton, Y. Huang, U. Paik, J. A. Rogers, Sci. Adv. 2016, 2, e1600418.
[3] J. Liu, T.-M. Fu, Z. Cheng, G. Hong, T. Zhou, L. Jin, M. Duvvuri, Z. Jiang, P. Kruskal, C. Xie, Z. Suo, Y. Fang, C. M. Lieber, Nat. Nanotechnol. 2015, 10, 629.
[4] A. Chortos, J. Liu, Z. Bao, Nat. Mater. 2016, 15, 937.
[5] H. Huang, S. Su, N. Wu, H. Wan, S. Wan, H. Bi, L. Sun, Front. Chem. 2019, 7, 399.
[6] C. Liu, Z. Yu, D. Neff, A. Zhamu, B. Z. Jang, Nano Lett. 2010, 10, 4863.
[7] Y. Rangom, X. Tang, L. F. Nazar, ACS Nano 2015, 9, 7248.
[8] Y. Chen, A. Amiri, J. G. Boyd, M. Naraghi, Adv. Funct. Mater. 2019, 29, 1901425.
[9] X. Chen, R. Paul, L. Dai, Natl. Sci. Rev. 2017, 4, 453.
[10] S. He, Y. Hu, J. Wan, Q. Gao, Y. Wang, S. Xie, L. Qiu, C. Wang, G. Zheng, B. Wang, H. Peng, Carbon N. Y. 2017, 122, 162.
[11] M. Ghidiu, M. R. Lukatskaya, M.-Q. Zhao, Y. Gogotsi, M. W. Barsoum, Nature 2015, 516, 78.
[12] M. Naguib, M. Kurtoglu, V. Presser, J. Lu, J. Niu, M. Heon, L. Hultman, Y. Gogotsi, M. W. Barsoum, Adv. Mater. 2011, 23, 4248.
[13] M. R. Lukatskaya, O. Mashtalir, C. E. Ren, Y. Dall'Agnese, P. Rozier, P. L. Taberna, M. Naguib, P. Simon, M. W. Barsoum, Y. Gogotsi, Science 2013, 341, 1502.
[14] B. Anasori, Y. Xie, M. Beidaghi, J. Lu, B. C. Hosler, L. Hultman, P. R. C. Kent, Y. Gogotsi, M. W. Barsoum, ACS Nano 2015, 9, 9507.
[15] B. Anasori, M. R. Lukatskaya, Y. Gogotsi, Nat. Rev. Mater. 2017, 2, 16098.
[16] K. Huang, Z. Li, J. Lin, G. Han, P. Huang, Chem. Soc. Rev. 2018, 47, 5109.
[17] A. Rafieerad, G. L. Sequiera, W. Yan, P. Kaur, A. Amiri, S. Dhingra, J. Mech. Behav. Biomed. Mater. 2020, 101, 103440.
[18] J. Yang, W. Bao, P. Jaumaux, S. Zhang, C. Wang, G. Wang, Adv. Mater. Interfaces 2019, 6, 1802004.
[19] M. Naguib, O. Mashtalir, M. R. Lukatskaya, B. Dyatkin, C. Zhang, V. Presser, Y. Gogotsi, M. W. Barsoum, Chem. Commun. 2014, 50, 7420.
[20] O. Mashtalir, M. R. Lukatskaya, M.-Q. Zhao, M. W. Barsoum, Y. Gogotsi, Adv. Mater. 2015, 27, 3501.
[21] A. Rafieerad, W. Yan, G. L. Sequiera, N. Sareen, E. Abu-El-Rub, M. Moudgil, S. Dhingra, Adv. Healthc. Mater. 2019, 8, 1900569.
[22] H. Lin, Y. Wang, S. Gao, Y. Chen, J. Shi, Adv. Mater. 2018, 30, 1703284.
[23] C. Dai, Y. Chen, X. Jing, L. Xiang, D. Yang, H. Lin, Z. Liu, X. Han, R. Wu, ACS Nano 2017, 11, 12696.
[24] H. Li, Z. Yao, J. Zhang, X. Cai, L. Li, G. Liu, J. Liu, L. Cui, J. Huang, SN Appl. Sci. 2020, 2, 671.
[25] B. R. Levine, S. Sporer, R. A. Poggie, C. J. Della Valle, J. J. Jacobs, Biomaterials 2006, 27, 4671.
[26] M.-D. Bermddez, F. J. Carrión, G. Martfnez-Nicolás, R. López, Wear 2005, 258, 693.
[27] D. M. Findlay, K. Welldon, G. J. Atkins, D. W. Howie, A. C. W. Zannettino, D. Bobyn, Biomaterials 2004, 25, 2215.
[28] Z. Liu, H. Lin, M. Zhao, C. Dai, S. Zhang, W. Peng, Y. Chen, Theranostics 2018, 8, 1648.
[29] G. Deysher, S. Sin, Y. Gogotsi, B. Anasori, Mater. Today 2018, 21, 1064.
[30] B. Ahmed, D. H. Anjum, M. N. Hedhili, Y. Gogotsi, H. N. Alshareef, Nanoscale 2016, 8, 7580.
[31] T. Li, L. Yao, Q. Liu, J. Gu, R. Luo, J. Li, X. Yan, W. Wang, P. Liu, B. Chen, W. Zhang, W. Abbas, R. Naz, D. Zhang, Angew. Chemie—Int. Ed. 2018, 57, 6115.
[32] J. Xuan, Z. Wang, Y. Chen, D. Liang, L. Cheng, X. Yang, Z. Liu, R. Ma, T. Sasaki, F. Geng, Angew. Chemie 2016, 128, 14789.
[33] W. Gao, T. Liu, Z. Zhang, M. Dou, F. Wang, J. Mater. Chem. A 2020, 8, 5525.
[34] I. E. Grey, W. G. Mumme, R. S. Roth, J. Solid State Chem. 2005, 178, 3308.
[35] L. Greenspan, J. Res. Natl. Bur. Stand.—A. Phys. Chem. 1977, 81A, 89.
[36] R. Syamsai, J. R. Rodriguez, V. G. Pol, Q. Van Le, K. M. Batoo, S. A. Farooq, S. Pandiaraj, M. R. Muthumareeswaran, E. H. Raslan, A. N. Grace, Sci. Rep. 2021, 11, 688.
[37] J. Wang, S. Kaskel, J. Mater. Chem. 2012, 22, 23710.
[38] A. Amiri, Y. Chen, C. B. Teng, M. Naraghi, Energy Storage Mater. 2020, 25, 731.
[39] M. R. Lukatskaya, S.-M. Bak, X. Yu, X.-Q. Yang, M. W. Barsoum, Y. Gogotsi, Adv. Energy Mater. 2015, 5, 1500589.
[40] R. B. Rakhi, B. Ahmed, M. N. Hedhili, D. H. Anjum, H. N. Alshareef, Chem. Mater. 2015, 27, 5314.
[41] B. Jiang, X. Ban, Q. Wang, K. Cheng, K. Zhu, K. Ye, G. Wang, D. Cao, J. Yan, J. Mater. Chem. A 2019, 7, 24374.
[42] Y. Wang, X. Wang, X. Li, Y. Bai, H. Xiao, Y. Liu, G. Yuan, Chem. Eng. J. 2021, 405, 126664.
[43] Z. Wang, S. Qin, S. Seyedin, J. Zhang, J. Wang, A. Levitt, N. Li, C. Haines, R. Ovalle-Robles, W. Lei, Y. Gogotsi, R. H. Baughman, J. M. Razal, Small 2018, 14, 1802225.
[44] S. Richter, M. Daring, M. Ebert, K. Bode, A. Müssigbrodt, P. Sommer, D. Husser, G. Hindricks, Circulation 2018, 137, 2408.
[45] J. S. Chae, N.-S. Heo, C. H. Kwak, W.-S. Cho, G. H. Seol, W.-S. Yoon, H.-K. Kim, D. J. Fray, A. T. E. Vilian, Y.-K. Han, Y. S. Huh, K. C. Roh, Nano Energy 2017, 34, 86.
[46] I. M. Mosa, A. Pattammattel, K. Kadimisetty, P. Pande, M. F. El-Kady, G. W. Bishop, M. Novak, R. B. Kaner, A. K. Basu, C. V. Kumar, J. F. Rusling, Adv. Energy Mater. 2017, 7, 1700358.
[47] N. Jung, S. Kwon, D. Lee, D.-M. Yoon, Y. M. Park, A. Benayad, J.-Y. Choi, J. S. Park, Adv. Mater. 2013, 25, 6854.
[48] X. Yang, C. Cheng, Y. Wang, L. Qiu, D. Li, Science 2013, 341, 534.
[49] S. Murali, N. Quarles, L. L. Zhang, J. R. Potts, Z. Tan, Y. Lu, Y. Zhu, R. S. Ruoff, Nano Energy 2013, 2, 764.
[50] Y. Zhu, S. Murali, M. D. Stoller, K. J. Ganesh, W. Cai, P. J. Ferreira, A. Pirkle, R. M. Wallace, K. A. Cychosz, M. Thommes, D. Su, E. A. Stach, R. S. Ruoff, Science 2011, 332, 1537.
[51] M. Heon, S. Lofland, J. Applegate, R. Nolte, E. Cortes, J. D. Hettinger, P.-L. Taberna, P. Simon, P. Huang, M. Brunet, Y. Gogotsi, Energy Environ. Sci. 2011, 4, 135.
[52] C. Liu, F. Li, L.-P. Ma, H.-M. Cheng, Adv. Mater. 2010, 22, E28.
[53] C. Couly, M. Alhabeb, K. L. Van Aken, N. Kurra, L. Gomes, A. M. Navarro-Suárez, B. Anasori, H. N. Alshareef, Y. Gogotsi, Adv. Electron. Mater. 2018, 4, 1700339.
[54] X. Wu, B. Huang, Q. Wang, Y. Wang, Chem. Eng. J. 2020, 380, 122456.
[55] A. Srivastava, G. L. Sequiera, K. N. Alagarsamy, C. Rockman-Greenberg, S. Dhingra, Stem Cell Res. 2021, 53, 102283.
[56] G. L. Sequiera, C. Rockman-Greenberg, S. Dhingra, Stem Cell Res. 2020, 48, 101964.
[57] G. L. Sequiera, A. Srivastava, K. N. Alagarsamy, C. Rockman-Greenberg, S. Dhingra, Cells 2021, 10, 568.
[58] E. Abu-El-Rub, N. Sareen, W. Yan, K. N. Alagarsamy, A. Rafieerad, A. Srivastava, V. Desiderio, S. Dhingra, Cell Death Dis. 2020, 11, 419.

1. A method for synthesizing a two-dimensional transition metal carbides and nitrides (MXenes)-metal oxide hybrid structure material comprising:
(a) providing a quantity of a MAX phase powder, where “M” represents an early transition metal, “A” represents an A group element and “X” represents carbon or nitrogen;
(b) chlorinating the MAX phase powder, thereby solubilizing the A group element and forming a chlorinated MX powder;
(c) etching the chlorinated MX powder with an oxide source, thereby forming an exfoliated nanocomposite; and
(d) heating the exfoliated nanocomposite, thereby forming the MXenes-M-oxide hybrid structure material.

2. The method according to claim 1 wherein the early transition metal is tantalum.

3. The method according to claim 1 wherein the MAX phase powder is selected from the group consisting of tantalum aluminium carbide (Ta₄AlC₃), vanadium aluminium carbide (V₄AlC₃), niobium aluminium carbide (Nb₂AlC₃ and Nb₂AlC), titanium aluminium carbide (Ti₃AlC₂), zirconium aluminium carbide (Zr₂AlC), and halfmium aluminium carbide (Hf₃AlC₂).

4. The method according to claim 1 wherein the MAX phase powder is tantalum aluminium carbide.

5. The method according to claim 1 wherein the MAX phase powder is chlorinated by treatment with HCl or HClO.

6. The method according to claim 1 wherein the MAX phase powder is chlorinated by treatment with HCl.

7. The method according to claim 6 wherein the HCl is 6M HCl.

8. The method according to claim 1 wherein the oxide source is selected from the group consisting of: KOH, NaOH, H₂O₂ and LiOH.

9. The method according to claim 1 wherein the oxide source is KOH.

10. The method according to claim 1 wherein the exfoliated nanocomposite is heated at about 200 to about 500 C, for about 2 to about 4 hrs.

11. The method according to claim 1 wherein the exfoliated nanocomposite is heated at about 220C for about 2 hrs.

12. A MXenes-oxide hybrid structure material prepared according to the method of claim 1.

13. A MXenes-oxide hybrid structure material.

14. The MXenes-oxide hybrid structure material according to claim 13 wherein the MXenes-oxide hybrid structure material is a MXene-tantalum oxides hybrid structure material.

15. (canceled)

16. (canceled)

17. (canceled)

18. (canceled)
